(19) United States
(12) Patent Application Publication
(10) Pub. No.: US 2016/0165732 A1
(43) Pub. Date: Jun. 9, 2016

(54) PRINTED CIRCUIT BOARD WITH EMBEDDED ELECTRONIC COMPONENT AND METHOD OF MANUFACTURING THE SAME

(71) Applicant: Samsung Electro-Mechanics Co., Ltd., Suwon-si (KR)

(72) Inventors: Myeong-Dae MOON, Busan (KR); Byung-Sub JUNG, Busan (KR)

(73) Assignee: Samsung Electro-Mechanics Co., Ltd., Suwon-si (KR)

(21) Appl. No.: 14/955,523

(22) Filed: Dec. 1, 2015

(30) Foreign Application Priority Data
Dec. 5, 2014 (KR) 10-2014-0174203

(51) Int. Cl. H05K 1/18; H05K 3/30

(52) U.S. Cl. CPC H05K 1/183; H05K 3/30

(57) ABSTRACT

A printed circuit board with embedded electronic component and a method of manufacturing the same are provided. The method of manufacturing a printed circuit board involves processing a cavity in a core substrate, attaching a support to one surface of the core substrate, inserting an electronic component into the cavity, affixing the electronic component to a side wall of the cavity by use of a liquid adhesive, removing the support, and stacking an insulation layer and a copper thin layer simultaneously on both surfaces of the core substrate.

### CROSS-REFERENCE TO RELATED APPLICATIONS

This application claims the benefit under 35 USC 119(a) of Korean Patent Application No. 10-2014-0174203, filed on Dec. 5, 2014, in the Korean Intellectual Property Office, the entire disclosure of which is incorporated herein for all purposes.

### BACKGROUND

1. Field

The following description relates to an electronic component embedded printed circuit board and a manufacturing method thereof.

2. Description of Related Art

With the advancement of the manufacturing technology of electronic devices, there exists a demand to produce lighter, thinner and smaller printed circuit boards that are embedded into electronic devices. However, since electronic components are mounted on the printed circuit boards, it is difficult to further reduce the thickness of electronic devices.

Accordingly, a technique of mounting electronic components that is different from the conventional surface mounting method, has been developed to cope with the trends toward thinner electronic devices. In this method, an active component such as an IC or a passive component such as resistance or a capacitor is mounted inside a printed circuit board. An example of a method of manufacturing electronic component-embedded printed circuit boards is described in Korea Patent Publication No. 2012-0042428.

However, the method of manufacturing printed circuit boards embedded with electronic components involves making cavities and generally requires a large amount of processing time, in comparison to the conventional printed circuit board manufacturing method in which the components are mounted on a surface of the printed circuit boards. Accordingly, these methods result in high manufacturing costs due to an increased amount of time and additional steps necessary, and result in a decreased efficiency in manufacturing time and decreased economic efficiency.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board including a core substrate having a cavity formed therein, an electronic component embedded in the cavity, and an adhesive layer affixing the electronic component to a side wall of the cavity.

The adhesive layer may be a cured liquid adhesive layer.

The cured liquid adhesive layer may be obtained by curing a UV curable liquid adhesive.

The general aspect of the printed circuit board may further include an insulation layer and a copper thin layer disposed on either surface of the core substrate.

The electronic component may include a component selected from a group consisting of a multilayer ceramic chip capacitor (MLCC), a low temperature co-fired ceramic capacitor (LTCC), a chip, a resistor, an integrated circuit (IC) chip and a semiconductor chip.

In another general aspect, a method of manufacturing a printed circuit board involves processing a cavity in a core substrate, attaching a support to one surface of the core substrate, inserting an electronic component into the cavity, affixing the electronic component to a side wall of the cavity by use of a liquid adhesive, removing the support, and stacking an insulation layer and a copper thin layer simultaneously on both surfaces of the core substrate.

The processing of the cavity may involve forming the cavity by using a CO₂ laser, a YAG (Yttrium, Aluminum, Garnet) laser, or a glass laser.

During the processing of the cavity, a size of the cavity may be set to be greater than that of the electronic component so as to form a gap having a width of 100 to 130 micrometers between the electronic component and the side wall of the cavity.

During the inserting of the electronic component into the cavity, the electronic component is at least one selected from a group consisting of a multilayer ceramic chip capacitor (MLCC), a low temperature co-fired ceramic capacitor (LTCC), a chip, a resistor, an integrated circuit (IC) chip and a semiconductor chip.

During the affixing of the electronic component, a UV curable liquid adhesive may be used as the liquid adhesive.

During the affixing of the electronic component, the liquid adhesive may be discharged by a minute nozzle.

The general aspect of the method may further involve, prior to the stacking of the insulation layer and the copper thin layer simultaneously on both surfaces of the core substrate, performing a plasma treatment process on both surfaces of the core substrate.

During the stacking of the insulation layer and the copper thin layer simultaneously on both surfaces of the core substrate, a high-temperature and high-pressure pressing process, in which heat and pressure are simultaneously applied, may be used.

The support may include a film-shaped adhesive tape or a plate-shaped curable resin.

In another general aspect, a method of manufacturing a printed circuit board involves positioning an electronic component in a cavity formed in a core substrate, affixing the electronic component to a side wall of the cavity by applying a liquid adhesive, stacking an insulation layer on both surfaces of the core substrate simultaneously in order to embed the electronic component inside the printed circuit board.

The general aspect of the method may further involve, prior to the stacking of the insulation layer, removing a support used to position the electronic component in the cavity.

The general aspect of the method may further involve, prior to the stacking of the insulation layer, electrically connecting the electronic component to an inner circuit disposed on the core substrate.

Other features and aspects will be apparent from the following detailed description, the drawings, and the claims.

### BRIEF DESCRIPTION OF DRAWINGS

FIG. 1 is a cross-sectional view illustrating an example of an electronic component embedded printed circuit board with an electronic component embedded therein.

FIG. 2 is a cross-sectional view illustrating a step of forming an inner cavity in accordance with an example of a method of manufacturing an electronic component embedded printed circuit board.

FIG. 3 is a cross-sectional view illustrating a step of attaching a support for temporarily fixing an electronic component in accordance with an example of a method of manufacturing an electronic component embedded printed circuit board.

FIG. 4 is a cross-sectional view illustrating a step of inserting an electronic component in accordance with an example of a method of manufacturing an electronic component embedded printed circuit board.

FIG. 5 is a cross-sectional view illustrating a step of coating and curing a liquid adhesive for fixing an electronic component in accordance with an example of a method of manufacturing an electronic component embedded printed circuit board.

FIG. 6 is a cross-sectional view illustrating a step of removing the support in accordance with an example of a method of manufacturing an electronic component embedded printed circuit board.

FIG. 7 is a cross-sectional view illustrating a step of performing a stacking process simultaneously on both surfaces of an electronic component disposed in the cavity in accordance with an example of a method of manufacturing an electronic component embedded printed circuit board.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

The terms used in the present specification are merely used to describe various examples, and are not intended to limit the present description. An expression used in the singular encompasses the expression of the plural, unless it has a clearly different meaning in the context. In the present specification, it is to be understood that the terms such as “including” or “having,” and the like, are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Terms such as “first”, “second”, “one surface (side)” and “the other surface (side)” can be used in merely distinguishing one element from other identical or corresponding elements, but the above elements shall not be restricted to the above terms.

When one element is described to be “coupled” to another element, it does not refer to a physical, direct contact between these elements only, but it shall also include the possibility of yet another element being interposed between these elements and each of these elements being in contact with said yet another element.

Unless otherwise defined, all terms used herein, including technical or scientific terms, have the same meanings as those generally understood by those with ordinary knowledge in the field of art to which the present description belongs. Such terms as those defined in a generally used dictionary are to be interpreted to have the meanings equal to the contextual meanings in the relevant field of art, and are not to be interpreted to have ideal or excessively formal meanings unless clearly defined in the present application.

Certain embodiments of the present description will be described below in detail with reference to the accompanying drawings. Those components that are the same or are in correspondence are rendered the same reference numeral regardless of the figure number, and redundant descriptions are omitted. Before describing certain embodiments of the present description, a general principle and a system for obtaining 3-dimensional information using holography will be first described below.

Hereinafter, an electronic component embedded printed circuit board and a method of manufacturing the same in accordance with certain embodiments of the present description will be described in detail with reference to the accompanying drawings.

Unlike a conventional printed circuit board in which an active component and a passive component share the same surface of a substrate, an electronic component embedded printed circuit board is a substrate having the active component or the passive component embedded therein. In this structure of the electronic component embedded printed circuit board, it is possible to obtain the space allowance of a space on the surface of the printed circuit board. Also, this structure makes it possible to increase the density of wire patterns, compared to the conventional printed circuit board, making it easier to develop a compact electronic device.

According to one example of a method of manufacturing an electronic component embedded printed circuit board, an insulation layer and a copper thin layer are stacked simultaneously on both surfaces of a core substrate after an electronic component is inserted in a cavity. According to one example of a printed circuit board, the printed circuit board includes a core substrate having a cavity formed therein, an electronic component embedded in the cavity, and an adhesive layer fixing the electronic component to a side wall of the cavity. The adhesive layer may be obtained by curing a liquid adhesive.

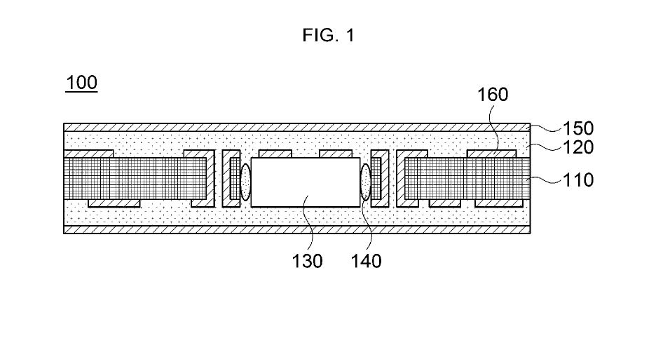

FIG. 1 illustrates a cross-sectional view of an example of an electronic component embedded printed circuit board in accordance with the present description. In the drawings, elements may not be illustrated in accordance with their actual sizes, and the thicknesses of layers and areas are exaggerated for clarity. That is, the size of one element may be exaggerated as compared to that of another element for clarity.

Referring to FIG. 1, the electronic component embedded printed circuit board 100 includes a first insulation layer 110, a second insulation layer 120, an electronic component 130 embedded in the first insulation layer 110, an adhesive layer 140 adhering the electronic component 130 to a side wall of the first insulation layer 110, a copper thin layer 150 and an inner circuit layer 160.

The first insulation layer 110 can be a core layer that is included in a one-layer printed circuit board, a double-layer printed circuit board or a multilayer printed circuit board.

FIG. 1 illustrates that, among a plurality of insulation layers constituting a substrate, only one insulation layer is used for having the electronic component 130 embedded therein. The first insulation layer 110 shown in FIG. 1 can be the substrate, or a buildup layer can be stacked on a surface above the first insulation layer 110.

The first insulation layer 110 can be made of, for example, thermosetting resin such as epoxy, thermoplastic resin such as polyimide or photocurable resin and the like. In case that the first insulation layer 110 is used as a core layer of the substrate, prepreg, which is resin filled with reinforcing members such as glass fibers and inorganic fillers, may be used.

Moreover, the electronic component 130 embedded in the first insulation layer 110 can be a passive component such as a multilayer ceramic chip capacitor (MLCC), a low temperature co-fired ceramic capacitor (LTCC), a chip, a resistor and the like, or an active component such as an integrated circuit (IC) chip and a semiconductor chip.

The second insulation layer 120 can be formed through the stacking of insulation materials, and can be cured by heating and compressing the insulation materials together. While the insulation materials are heated and compressed together, some portions of the insulation materials can flow into a space between the electronic component 130 and a cavity of the first insulation layer 110 and can be cured such that the position of the electronic component 130 is fixed.

Meanwhile, a liquid adhesive may be used as the adhesive layer 140. By coating or injecting a liquid adhesive into a space between the electronic component 130 and a side wall of the first insulation layer 110, the electronic component 130 may be permanently fixed to the inside of the cavity formed in the first insulation layer 110. In this embodiment, a UV curable liquid adhesive, which responds to ultraviolet (UV) rays, can be used as the liquid adhesive. However, it shall be understood that the present description is not limited to this example; in another example, a different material may be substituted as the liquid adhesive as long as it is a liquid adhesive that is suitable for use in a printed circuit board.

Moreover, after the second insulation layer 120 and the copper thin layer 150 are stacked simultaneously on both surfaces of the first insulation layer 110, the copper thin layer 150 is etched to form an outer circuit layer. Since the outer circuit layer is a metallic pattern patterned in a two-dimensional configuration, the outer circuit layer can be used as a ground pattern forming a ground portion, used as a power pattern for supplying power and used as a signal pattern for transferring a signal and the like. Some portions of the outer circuit layer can be used as a pad for electrical connection with electronic components, which will be mounted on the pad later.

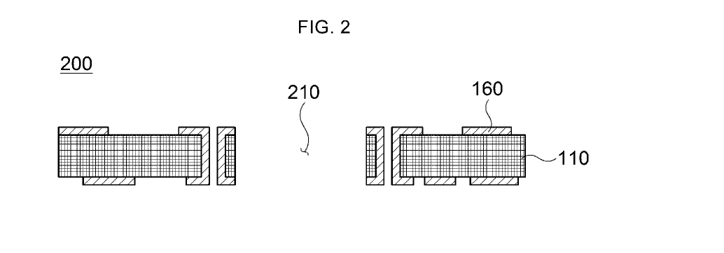

Hereinafter, steps of manufacturing the example of the electronic component-embedded printed circuit board illustrated in FIG. 1 will be described with reference to FIGS. 2 to 7.

FIG. 2 illustrates an example of a step of forming an inner cavity of the electronic component-embedded printed circuit board.

A cavity is an inner space that is formed to have an electronic component embedded inside a substrate. By forming the cavity in the substrate, the electronic component can embedded in the cavity of the substrate, and thus it is possible to make the product smaller and thinner.

Referring to FIG. 2, the cavity 210 can be formed by laser drilling the core substrate 200 or by drilling the core substrate 200 using CNC. In this embodiment of the present description, the cavity 210 is formed by a laser drilling process, improving the precision of the cavity 210 compared to the cavity 210 formed by a drilling process.

The laser used for forming the cavity 210 can be any one of CO₂ laser having higher output, YAG (Yttrium, Aluminum, Garnet) laser and glass laser. However, it shall be understood that the present description is not limited to this example.

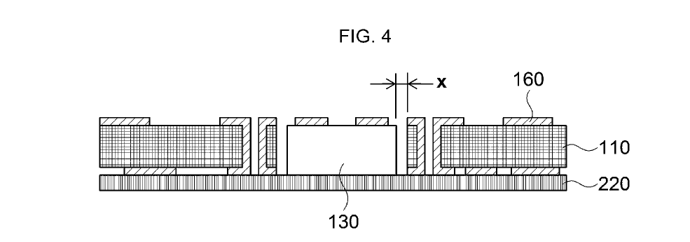

The size of the cavity 210 formed in the core substrate 200 may be greater than that of the electronic component in order to have the electronic component embedded therein. However, if the size of the cavity is formed much greater than that of the electronic component, a gap formed between the cavity 210 and the electronic component may not be completely filled with the insulation material of the insulation layer, and thus a void may be formed within the gap. In the case where the electronic component is adhered to a side wall of the cavity 210 by using a liquid adhesive, similar to the present embodiment described herein, the liquid adhesive may flow down and cause problems because the gap between them is too great. Thus, for example, while the size of the cavity 210 may be greater than that of the electronic component, the cavity 210 is formed to have a gap of approximately 100 to 130 micrometers between the electronic component and a wall of the cavity such that the viscosity of the liquid adhesive is maintained in order to have the liquid adhesive fill the gap and the liquid adhesive is prevented from leaking out of the gap. The width x of a gap between a wall of the cavity 210 and the electronic component is illustrated, for example, in FIG. 4.

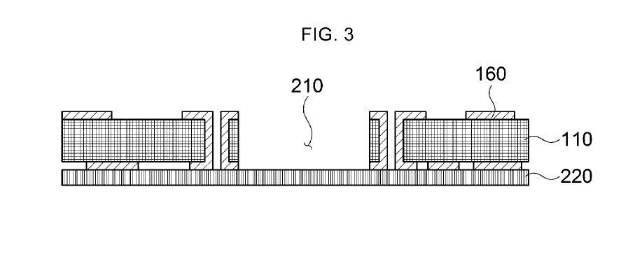

FIG. 3 illustrates a step of attaching a support for temporarily fixing an electronic component in accordance with an example of the method of manufacturing an electronic component embedded printed circuit board.

Referring to FIGS. 2 and 3, a support 200, which provides adhesion on one surface thereof only, can be attached to one surface of the core substrate 200. While the electronic component is inserted in the cavity, the support 220 temporarily maintains the position of the electronic component within the cavity 210. That is, the support 220 functions to prevent the electronic component from being detached from the cavity 210 while the next processes are performed. According to one example, a film-shaped adhesive tape or plate-shaped curable resin such as, for example, PET, PE or PVC, in a jig shape can be used as the support 220. However, the present description is not limited to what is described herein, and various types of supports may be used in another example.

The adhesive tape may be made of a flexible material may be used, a plate-shaped curable resin comprised of PET, PE or PVC formed in a jig shape exhibits good mechanical strength in comparison to an adhesive tape. Thus, the plate-shaped curable resin can easily support electronic components within the cavity 210 regardless of various types of the electronic components. That is, the plate-shaped curable resin in a jig shape can improve deflection that may be caused by the weight of the electronic component mounted thereon and thus support a heavy active component stably, while the adhesive tape is not strong enough to support heavy active components such as an IC, which tends to be heavier that a passive component, and thus may deform an adhesive tape due to the weight of the electronic component mounted thereon.

FIG. 4 illustrates a step of inserting an electronic component in accordance with an example of the method of manufacturing an electronic component embedded printed circuit board.

Referring to FIGS. 2 and 4, the electronic component 130 is inserted into the cavity 210 so that the electronic component 130 can be coupled to an adhesive surface of the support 220, which has been attached to the one surface of the core substrate 200.

The electronic component 130 can be a passive component such as MLCC, LTCC, a chip and resistance or an active component such as an IC chip and a semiconductor chip.

Once the electronic component 130 is attached to the adhesive surface of the support 220, the position of the inserted electronic component 130 can be maintained within the cavity 210 without being detached therefrom while the next processes in which the electronic component 130 is fixed to the side wall of the cavity 210 by use of a liquid adhesive are performed. According to one example, the cavity 210 may be formed to correspond closely to the shape and size of the electronic component 130 such that a width x of the gap ranges between approximately 100 to 130 micrometers.

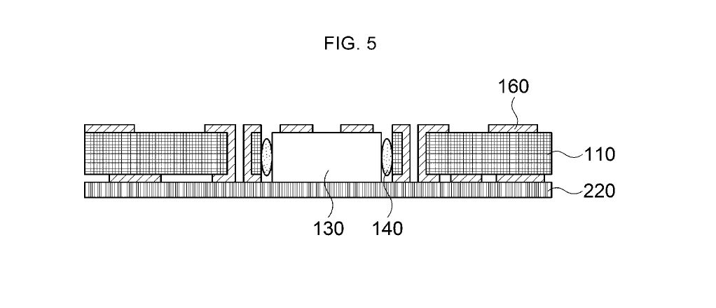

FIG. 5 illustrates a step of coating and curing a liquid adhesive for fixing an electronic component in accordance with an example of the method of manufacturing an electronic component embedded printed circuit board.

Referring to FIGS. 2 and 5, a liquid adhesive can be coated between the electronic component 130 and the side wall of the cavity 210 such that an adhesive layer 140 is formed in order to permanently stabilize the electronic component 130 within the cavity 210.

For example, a UV curable liquid adhesive, which responds to ultraviolet (UV) rays, can be used for the liquid adhesive. Also, the electronic component 130 can be fixed to the side wall of the cavity 210 by use of a thermosetting liquid adhesive. However, the present description is not limited to what is described therein, and various types of liquid adhesives may be included in the present embodiment.

The adhesive layer 140 can be formed by discharging a desirable amount of the liquid adhesive by use of a minute nozzle. The adhesive layer 140 may function to stabilize the electronic component 130 within the cavity 210 without the support 220.

According to one example, after the liquid adhesive is applied, the liquid adhesive can be cured through a UV curing process so as to form the adhesive layer 140 between the electronic component 130 and the side wall of the cavity 210. As a result, the electronic component 130 may be affixed within the cavity 210 of the core substrate 200.

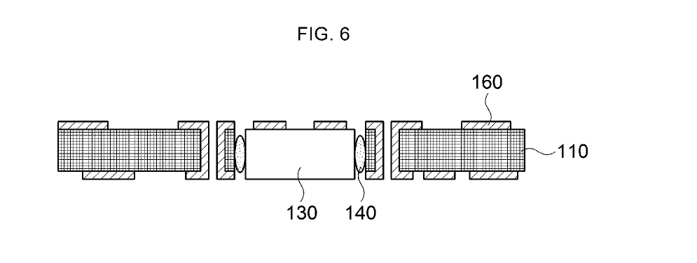

FIG. 6 illustrates a step of removing the support in accordance with an example of the method of manufacturing an electronic component embedded printed circuit board.

Referring to FIGS. 1, 2, 3 and 6, the support 220, which is attached to the one surface of the core substrate 200, can be removed. That is, since the electronic component 130 is permanently fixed within the cavity 210 of the core substrate 200 by forming the adhesive layer 140, which is formed through the coating and curing processes of the liquid adhesive, the support 220 is no longer needed to stabilize the electronic component 130.

The support 220 is removed to perform the next processes in which the second insulation layer 120 and the copper thin layer 150 are stacked on both surfaces of the core substrate 200 simultaneously.

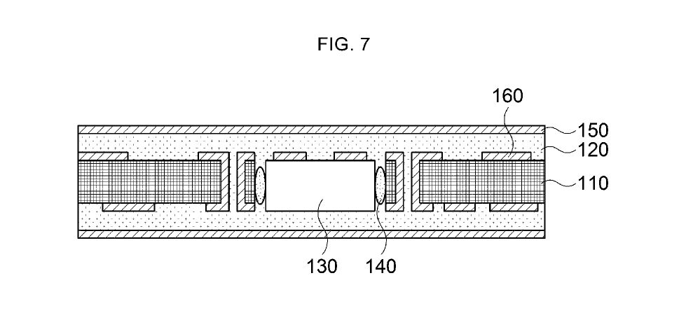

FIG. 7 illustrates a step of performing a stacking process simultaneously on both surfaces of an electronic component embedded printed circuit board in accordance with an example of the method of manufacturing an electronic component embedded printed circuit board.

Referring to FIGS. 2, 3 and 7, when the electronic component 130 is affixed within the cavity 210 through the adhesive layer 140, the second insulation layer 120 and the copper thin layer 150 can be stacked simultaneously on both surfaces of the first insulation layer 110.

For example, prior to the simultaneous stacking of the second insulation layer 120 and the copper thin layer 150, a plasma process can be performed. The plasma process can be performed to form desirable roughness of a stacking surface before the second insulation layer 120 and the copper thin layer 150 are stacked. Moreover, the plasma process can be performed as a preliminary treatment process in order to clean the surrounding area at which the support 220 was attached.

In an example in which an adhesive layer 140 is not used to fix the electronic component 130 within the cavity 210, the electronic component 130 may be fixed within the cavity 210 of the core substrate 200 by using only the support 220. In this case, the second insulation layer 120 and the copper thin layer 150 are stacked on one surface, which is where the support 220 is not attached, of the core substrate 200 first, and then the second insulation layer 120 and the copper thin layer 150 are stacked on the other surface, which is where the support 220 is attached, thereof, after the support 220 is removed in order to stack the second insulation layer 120 and the copper thin layer 150 while the electronic component 130 is fixed within the cavity 210 of the substrate 200 through the support 220.

However, according to one example in accordance with the present description, since the adhesive layer 140 functions to fix the electronic component 130 within the cavity 210 without having to have the support 220 formed on the other surface of the core substrate 200 while the electronic component 130 is permanently fixed within the cavity 210 by the adhesive layer 140, it is possible to simultaneously stack the second insulation layer 120 and the copper thin layer 150 on either or both surfaces of the first insulation layer 110.

In this example, the stacking of the second insulation layer 120 and the copper thin layer 150 can be performed by a high-temperature and high-pressure pressing process, in which heating and pressing are performed simultaneously.

Accordingly, since the second insulation layer 120 and the copper thin layer 150 are simultaneously stacked on both surfaces of the core substrate 200 in accordance with certain embodiments of the present description, it is possible to lower the manufacturing cost and to simplify the manufacturing processes because some key steps of the conventional manufacturing processes are omitted. This saves lead time and money in a much more simple and cost-effective way, compared to the conventional manufacturing processes.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a core substrate having a cavity formed therein;
an electronic component embedded in the cavity; and
an adhesive layer affixing the electronic component to a side wall of the cavity.

2. The printed circuit board of claim 1, wherein the adhesive layer comprises a cured liquid adhesive.

3. The printed circuit board of claim 2, wherein the cured liquid adhesive is obtained by curing a UV curable liquid adhesive.

4. The printed circuit board of claim 1, further comprising an insulation layer and a copper thin layer disposed on either surface of the core substrate.

5. The printed circuit board of claim 1, wherein the electronic component comprises a component selected from a group consisting of a multilayer ceramic chip capacitor (MLCC), a low temperature co-fired ceramic capacitor (LTCC), a chip, a resistor, an integrated circuit (IC) chip and a semiconductor chip.

6. A method of manufacturing a printed circuit board, the method comprising:
processing a cavity in a core substrate;
attaching a support to one surface of the core substrate;
inserting an electronic component into the cavity;
affixing the electronic component to a side wall of the cavity by use of a liquid adhesive;
removing the support; and
stacking an insulation layer and a copper thin layer simultaneously on both surfaces of the core substrate.

7. The method of claim 6, wherein the processing of the cavity comprises forming the cavity by using a CO₂ laser, a YAG (Yttrium, Aluminum, Garnet) laser, or a glass laser.

8. The method of claim 6, wherein, during the processing of the cavity, a size of the cavity is set to be greater than that of the electronic component so as to form a gap having a width of 100 to 130 micrometers between the electronic component and the side wall of the cavity.

9. The method of claim 6, wherein, during the inserting of the electronic component into the cavity, the electronic component is at least one component selected from a group consisting of a multilayer ceramic chip capacitor (MLCC), a low temperature co-fired ceramic capacitor (LTCC), a chip, a resistor, an integrated circuit (IC) chip and a semiconductor chip.

10. The method of claim 6, wherein, during the affixing of the electronic component, a UV curable liquid adhesive is used as the liquid adhesive.

11. The method of claim 6, wherein, during the affixing of the electronic component, the liquid adhesive is discharged by a minute nozzle.

12. The method of claim 6, further comprising, prior to the stacking of the insulation layer and the copper thin layer simultaneously on both surfaces of the core substrate, performing a plasma treatment process on both surfaces of the core substrate.

13. The method of claim 6, wherein, during the stacking of the insulation layer and the copper thin layer simultaneously on both surfaces of the core substrate, a high-temperature and high-pressure pressing process, in which heat and pressure are simultaneously applied, is used.

14. The method of claim 6, wherein the support comprises a film-shaped adhesive tape or a plate-shaped curable resin.

15. A method of manufacturing a printed circuit board, the method comprising:
positioning an electronic component in a cavity formed in a core substrate;
affixing the electronic component to a side wall of the cavity by applying a liquid adhesive;
stacking an insulation layer on both surfaces of the core substrate simultaneously in order to embed the electronic component inside the printed circuit board.

16. The method of claim 15, further comprising, prior to the stacking of the insulation layer, removing a support used to position the electronic component in the cavity.

17. The method of claim 15, further comprising, prior to the stacking of the insulation layer, electrically connecting the electronic component to an inner circuit disposed on the core substrate.
